(19) United States
(12) Patent Application Publication
(10) Pub. No.: US 2025/0081491 A1
(43) Pub. Date: Mar. 6, 2025

(54) TRENCH-GATED SWITCH WITH EPITAXIAL P-BODY LAYER HAVING HIGHER DOPED TOP PORTION

(71) Applicant: PAKAL TECHNOLOGIES, INC, SAN FRANCISCO, CA (US)

(72) Inventors: Vladimir Rodov, Seattle, WA (US); Paul M. Moore, Hillsboro, CA (US)

(73) Assignee: PAKAL TECHNOLOGIES, INC, SAN FRANCISCO, CA (US)

(21) Appl. No.: 18/808,080

(22) Filed: Aug. 19, 2024

Related U.S. Application Data
(60) Provisional application No. 63/536,403, filed on Sep. 2, 2023.

(51) Int. Cl. H01L 29/745; H01L 21/265; H01L 29/40; H01L 29/66

(52) U.S. Cl. CPC H10D 18/655; H01L 21/26513; H10D 18/01; H10D 64/117

(57) ABSTRACT

In a vertical switch having various doped layers, such as npnp or npn layers, and an array of trenched gates, a p-body layer is formed over an n-drift layer. A portion of the p-body layer is inverted by the voltage on the gate to form an n-channel to turn the device on. In a conventional device, the p-body layer is formed by implantation of p-dopants into the n-layer and then diffused. Since the p-body is fairly thick, diffusion takes a long time, resulting in the various layers having poor definition and imprecise characteristics. The device is improved by forming the p-body by epitaxial growth and varying the p-dopant concentration in the p-body to achieve the desired device characteristics. The top portion of the p-body may be enhanced by an implantation of additional p-dopants to achieve a desired turn-on voltage but not affecting the breakdown voltage of the device.

### CROSS-REFERENCE TO RELATED APPLICATIONS

This application is based on provisional application Ser. No. 63/536,403, filed Sep. 2, 2023, by Vladimir Rodov et al., assigned to the present assignee and incorporated herein by reference.

### FIELD OF THE INVENTION

This invention relates to insulated trench gate power devices, such as vertical and lateral MOSFETs, vertical and lateral insulated gate bipolar transistors (IGBTs), vertical and lateral insulated gate turn-off (IGTO) devices, and other types of semiconductor devices that are generally used to switch high current/high voltage loads and, in particular, to a novel body region structure that increases breakdown voltage, sets a precise turn-on voltage, improves the control of dopant diffusion, and improves performance.

### BACKGROUND

Applicant's U.S. Pat. No. 8,878,238, incorporated by reference, discloses a vertical power device which will be used as an example of one of many types of power devices that can benefit from the present invention. The power device from U.S. Pat. No. 8,878,238 will be described in detail, and the invention will later be described as a modification to such a device, and other insulated trench gate power devices, rather than repeating a detailed description of the prior art portion of the inventive structure.

Prior art FIG. 1 is a cross-sectional view of a small portion of a vertical power device 10 described in U.S. Pat. No. 8,878,238 that can benefit from the present invention. Although FIG. 1 just shows an edge portion of the cellular power device 10, the invention applies to all areas within the cellular array.

Three cells are shown having vertical gates 143, consisting of doped polysilicon, formed in insulated trenches 141A. Trench 141B is for a polysilicon connection to all the gates 143 and may not be considered a cell. A 2-dimensional array of the cells forming strips or a rectangular mesh may be formed in a common, lightly-doped p-well 107 (acting as a p-base), and the cells are connected in parallel.

Trenched gates are used because they take up very little silicon real estate, and vertical devices can typically have a breakdown voltage that is higher than a lateral device (horizontal gates on top).

N+ regions 129, forming sources, surround some or all of the gates 143 and are contacted by a top, metal cathode electrode 127 having a cathode terminal 101. The n+ regions 129 may be formed by implantation or by other known dopant introduction methods.

The vertical gates 143 are insulated from the p-well 107 by an oxide layer 145. The gates 143 are connected together outside the plane of the drawing and are coupled to a gate voltage via a metal gate electrode 109 (which may be a gate pad coupled to a lead of the die) directly contacting the polysilicon in the trench 141B. A patterned dielectric layer 119 insulates the gate electrode 109 from the p-well 107 and insulates the gates 143 from the cathode electrode 127.

Guard rings 113 near the edge of the die reduce field crowding for increasing the breakdown voltage. The guard rings 113 are contacted by metal 161 and 163, which are insulated from the n-drift layer 106 by field oxide 117.

A vertical npnp semiconductor layered structure is formed. There is a bipolar pnp transistor formed by a p+ substrate 104, an epitaxially grown n-drift layer 106 (acting as an n-base), and the p-well 107. There is also a bipolar npn transistor formed by the n+ regions 129, the p-well 107, and the n-drift layer 106. An n-type buffer layer 105, with a dopant concentration higher than that of the n-drift layer 106, reduces the injection of holes into the n-drift layer 106 from the p+ substrate 104 when the device is conducting. A bottom anode electrode 103, having an anode terminal 102, contacts the substrate 104, and the top cathode electrode 127, having a cathode terminal 101, contacts the n+ regions 129 and also contacts the p-well 107 at selected locations. The p-well 107 surrounds the gate structure, and the n-drift layer 106 extends to the surface around the p-well 107.

When the anode electrode 103 is forward biased with respect to the cathode electrode 127, but without a sufficiently positive gate bias, there is no current flow, since there is a reverse biased vertical pn junction and the product of the betas (gains) of the pnp and npn transistors is less than one (i.e., there is no regeneration activity).

When the gate 143 is sufficiently biased with a positive voltage (relative to the n+ regions 129), such as 2-5 volts, an inversion layer is formed around the gate 143, and electrons from the n+ regions 129 become the majority carriers along the gate sidewalls and below the bottom of the trenches in the inversion layer, causing the effective width of the npn base (the portion of the p-well 107 between the n-layers) to be reduced. As a result, the beta of the npn transistor increases to cause the product of the betas to exceed one. This condition results in “breakover,” when holes are injected into the lightly doped n-drift layer 106 and electrons are injected into the p-well 107 to fully turn on the device. Accordingly, the gate bias initiates the turn-on, and the full turn-on (due to regenerative action) occurs when there is current flow through the npn transistor as well as current flow through the pnp transistor.

When the gate bias is taken to zero, such as the gate electrode 109 being shorted to the cathode electrode 127, or taken negative, the power device 10 turns off, since the effective base width of the npn transistor is increased to its original width.

The device 10 is intended to be used as a high voltage/high current switch with very low voltage drop when on. The maximum voltage for proper operation is specified in a data sheet for the device 10.

The device 10 is similar to many other types of trenched, high current/high voltage insulated-gate power switches in that it is cellular, the trenches are filled with doped polysilicon, and all the gates are connected together to a single driver.

One issue with the device of FIG. 1 and with similar trench gate devices having a p-well 107 (or p-body), is that the p-dopants implanted into the top of the n-drift layer 106 to form the p-well 107 need a long diffusion time due to the relatively large width and depth of the p-well 107. The implanted dopants must be diffused up and down until fairly uniformly distributed. This may take on the order of an hour.

FIG. 2 illustrates the net dopant concentration vs. depth into the wafer prior to the formation of the n+ regions 129. Note how the p-dopants in the p-well 107 and the n-dopants in the drift layer 106 have cancelled each other out to cause a fairly wide low net doping area near the pn junction. This is due to the long diffusion time of the p-dopants, which also causes the n-dopants to diffuse upward. This results in a non-ideal net dopant concentration in the p-well 107 and a lack of control over the characteristics of the p-well 107 and the n-drift layer 106 near the trench gates (formed later). Thus, there is a lack of independent control of the turn-on voltage, the breakdown voltage, and the on-voltage (voltage drop across the device when on).

FIG. 3 illustrates the net doping concentration after the n-dopants have been implanted in the top of the p-well 107 and then diffused to form the n+ regions 129 (sources). After the diffusions, the p-well 107 has non-ideal characteristics. The net dopant concentration in the p-well 107 adjacent to the gates affects the turn-on voltage Vt (or threshold voltage), the breakdown voltage, and the on-voltage across the device. A higher net doping concentration increases the turn-on voltage, potentially increases breakdown voltage due to less depletion of the p-well 107 directly below the trenched gates, and increases the on-voltage due to less inversion of the p-well 107 when the device is on. As seen, there are tradeoffs between having higher net dopant concentrations and lower net dopant concentrations in the p-well 107.

FIG. 4 shows the net doping concentration near a generic pn junction where the n and p implanted dopants have a long diffusion time. Note how the diffused dopants cancel each other out (overlap) for a wide region near the pn junction. In contrast, FIG. 5 shows the same silicon but with a much shorter diffusion time, resulting in the n and p regions being more defined with more uniform net dopant concentrations. The dopant profile of FIG. 5 is preferred over the dopant profile of FIG. 4. However, the profile of FIG. 5 may not be achievable with large implanted p-wells.

Hence, it is desirable to achieve a more controllable vertical doping profile in the p-well so multiple characteristics of the p-well can be independently controlled with better precision.

### SUMMARY

The inventive technique improves the performance of all trenched gate devices, whether used as an on/off switch or an analog device. The technique can be used with both vertical and lateral devices.

Instead of a p-body (or p-well) being formed in an n-drift layer in a switching device by implantation and dopant diffusion, the p-body is formed by p-doping during epitaxial layer growth over the n-drift layer. There is no need for a diffusion step. This greatly reduces the diffusion of p-dopants into the n-drift layer and the diffusion of n-dopants into the p-body to create a fairly uniformly doped and defined p-body layer. After the epitaxial p-body layer is formed, p-dopants can be implanted to a shallow depth through the top of the p-body layer and quickly diffused to form a relatively thin layer of higher p-concentration material near the “top” of the inversion channels created by the trenched gates.

N-dopants are then implanted into the top p-layer and quickly diffused (since the layer is thin) to form the n+ source regions.

Next, the trenches for the gates are formed. The trenches in the active area of the device terminate in the p-body layer, and the trenches in the termination area extend down into the n-drift layer. A thin oxide is then formed on the trench walls, and the insulated trenches are filled with doped polysilicon to form gates (or gate electrodes). There are no n+ source regions or implanted top p-layer in the termination area since it is intended to be inactive and only serves to spread the voltage potential between the active area and the edges of the die to improve the breakdown voltage.

The remaining features of the switching device are then formed, which may be similar to the prior art.

The above-described techniques form an npnp layered IGTO device that is an improvement over the IGTO device of FIG. 1.

Besides forming a device with a much faster diffusion time (which enables better control over the characteristics of the various doped regions), the turn-on voltage, the breakdown voltage, and the on-voltage can be independently controlled. Increasing the p-dopant concentration in the epitaxial p-body layer increases the breakdown voltage since there is less depletion under the trenches when the device is off or when there is a reverse voltage condition. In contrast, if the p-dopants were implanted and diffused, there would be a significant gradient of the net p-type dopant concentration with depth into the wafer, causing the p-type doping to be too high near the top surface and too low near the bottom of the p-body. Thus, tradeoffs would have to be made between turn-on voltage and breakdown voltage.

By forming a shallow, upper enhanced p-layer by implantation and diffusion, the p-layer directly under the n+ sources can have the optimal net p-type concentration for achieving the desired gate turn-on voltage while not affecting the breakdown voltage.

Other advantages exist.

In other embodiments, the gate trenches in the active area extend down into the n-drift layer, and the device forms an npn-layered MOSFET device where a turned-on gate creates an n-type inversion channel between the n+ sources and the n-drift layer. For the MOSFET, the bottom layer is an n+ substrate on which is formed an anode electrode. Other devices, such as an IGBT, may also be fabricated.

The above-described approaches work with all types of trenched, insulated-gate devices. The device power electrodes may be on opposite sides of the die (vertical) or on the same side of the die (lateral).

Other embodiments are disclosed.

### BRIEF DESCRIPTION OF THE DRAWINGS

FIG. 1 is copied from Applicant's U.S. Pat. No. 8,878,238 and is a cross-section of an edge of a vertical switch having an array of insulated trench gates connected in parallel.

FIG. 2 is a graph (profile) of net dopant concentration vs. wafer depth after the p-well of FIG. 1 is formed using ion implantation and a long diffusion time.

FIG. 3 illustrates the dopant profile after the n+ source regions of FIG. 1 are formed.

FIG. 4 is generic and illustrates how a long-time diffusion of dopants creates a gradual gradient in n or p net doping concentration due to dopant overlap, which prevents optimizing the characteristics of regions in a power switch.

FIG. 5 is generic and illustrates the benefits of short-time diffusion of dopants, where the doped regions are better defined, enabling the regions to have more optimal and predictable characteristics.

FIG. 6 illustrates one embodiment of the invention and shows the formation of an epitaxially grown p-body layer over the n-drift layer for a device ultimately similar to that of FIG. 1.

FIG. 7 illustrates the implantation and short-time diffusion of p-dopants in the top surface of the epitaxially grown p-body layer of FIG. 6 to form a higher concentration p-layer abutting the trenched gates to control the gate turn-on voltage, while customizing the epitaxially grown p-body layer for optimizing breakdown voltage and on-voltage.

FIG. 8 illustrates the use of the present invention in a device similar to that of FIG. 1.

FIG. 9 illustrates the net dopant profile of the device of FIG. 8 next to a gate trench in the active area, showing well-defined and optimized doped regions for customizing turn-on voltage, breakdown voltage, and on-voltage (voltage drop).

Elements that are the same or equivalent in the various figures may be labeled with the same numeral.

### DETAILED DESCRIPTION

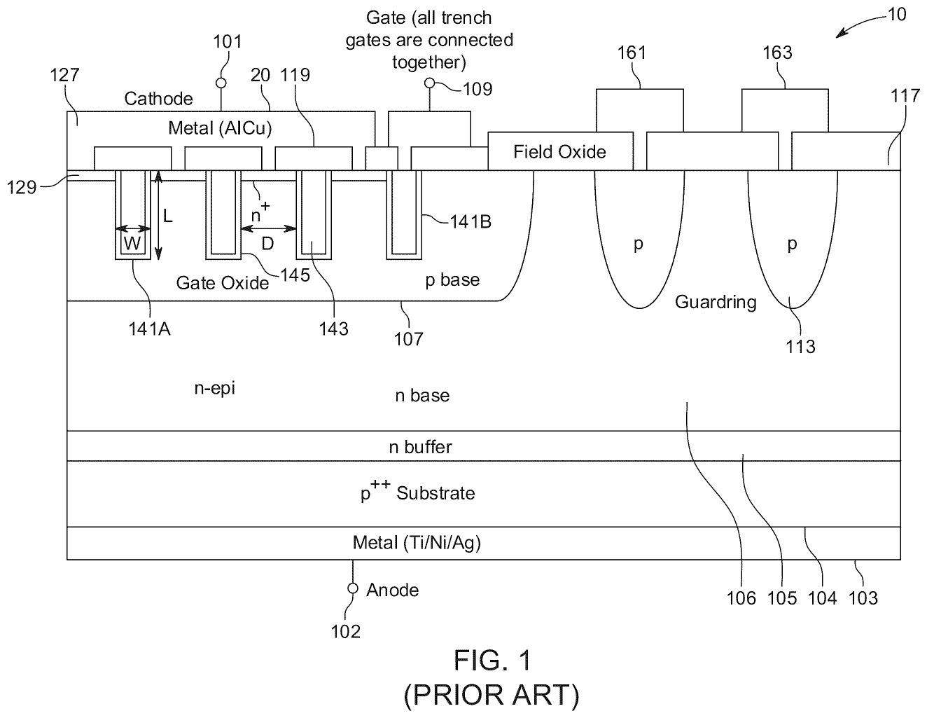

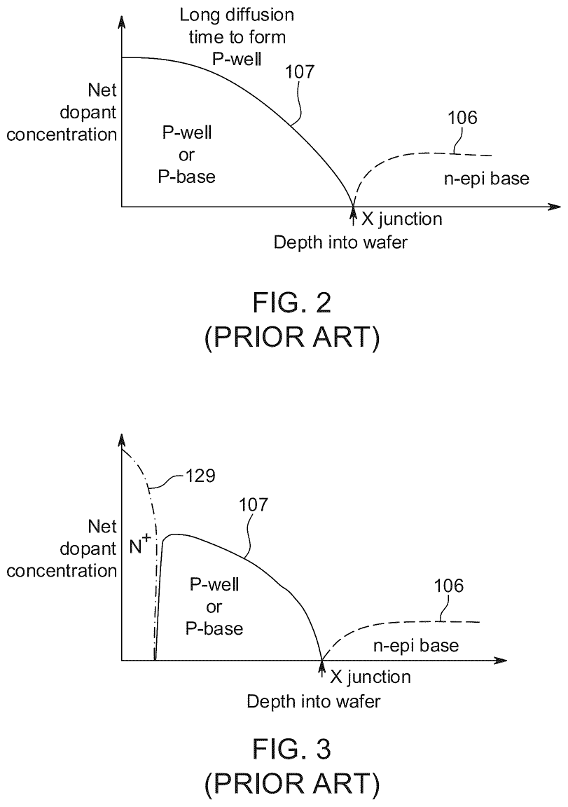

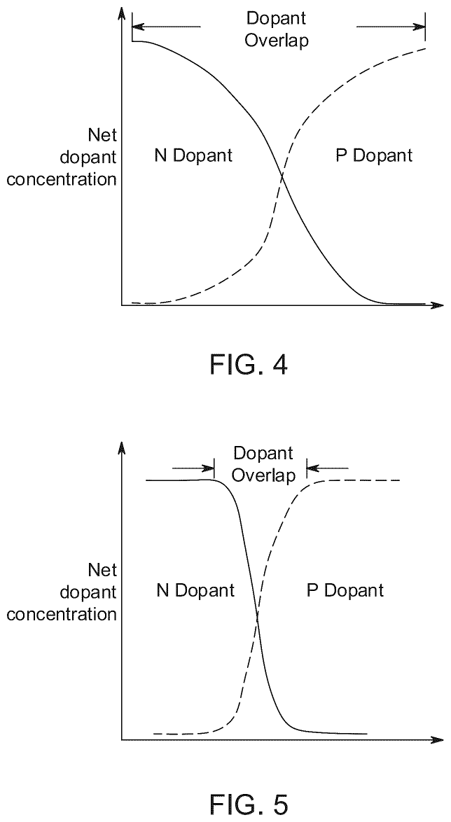

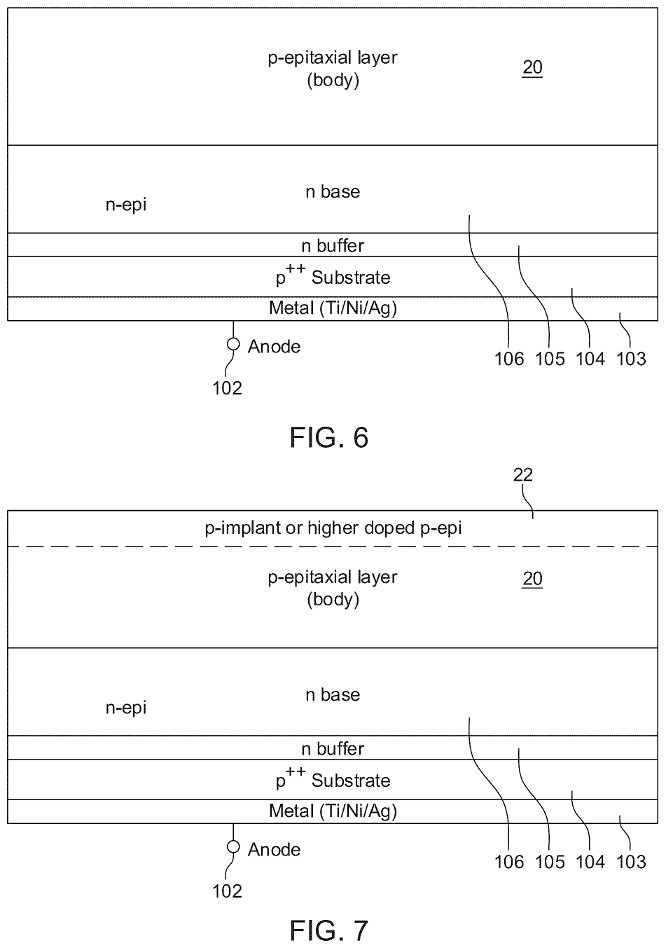

FIG. 6 is a cross-sectional view of a portion of an Insulated Gate Turn Off Device during fabrication. The layers 103-106 may be the same as in FIG. 1. Instead of a p-body or p-well being formed by ion implantation and diffusion into the epitaxial n-drift layer 106, a new p-epitaxial layer is formed which is the p-body 20. If the wafer is silicon, a silicon epitaxial layer is formed while introducing p-dopants into the growth chamber. Epitaxial growth temperature is on the order of 1000 degrees C. and the growth rate is typically between 1-10 microns per minute. In one embodiment, the p-body 20 has a thickness less than 20 microns.

In contrast, for a deep implant and diffusion, the required diffusion time to form a p-body may be up to 10 hours at 1000 degrees C. Therefore, the required time to form the p-body 20 by epitaxial growth is much less than the time needed for diffusion of the p-dopants in the n-drift layer 106. As a result, there is much less diffusion of n-dopants from the n-drift layer 106 into the p-body 20 and much less diffusion of p-dopants into the n-drift layer 106, resulting in more well-defined regions and more uniform dopant distribution.

The thickness of the various layers in FIG. 6 depends on the requirements of the device, and such required thicknesses can be determined by simulation.

FIG. 7 illustrates forming a higher doped p-layer 22 (enhanced body layer) in the top portion of the p-body 20. This may be done by a shallow ion implant of p-dopants into the p-body 20 followed by a short-time diffusion. Alternatively, during the epitaxial growth process for forming the p-body 20, the p-dopant gas may be increased to increase the p-dopant concentration in the p-layer 22 or to vary the dopant concentration in any way.

This enhanced p-layer 22 affects the turn-on gate voltage Vt of the device, where an increased dopant concentration raises the Vt. The dopant concentration in the p-body 20 is therefore independently controlled to modify a breakdown voltage of the device. For example, a very low dopant concentration in the p-body 20 would result in a depletion region reaching up to the gate trenches and causing a breakdown through the gate oxide. However, such a low dopant concentration also allows for a larger inversion channel when the device is turned on, allowing a higher current density. The p-body 20 next to a gate trench may be inverted at a low gate voltage prior to the device turning on, since the p-layer 22 has not been inverted. A slight increase in gate voltage then turns on the device by inverting the p-layer 22. Therefore, the turn-on speed may be increased. So, the p-body 20 dopant concentration can be adjusted to independently control certain device characteristics, while the p-layer 22 can be controlled for achieving other device characteristics.

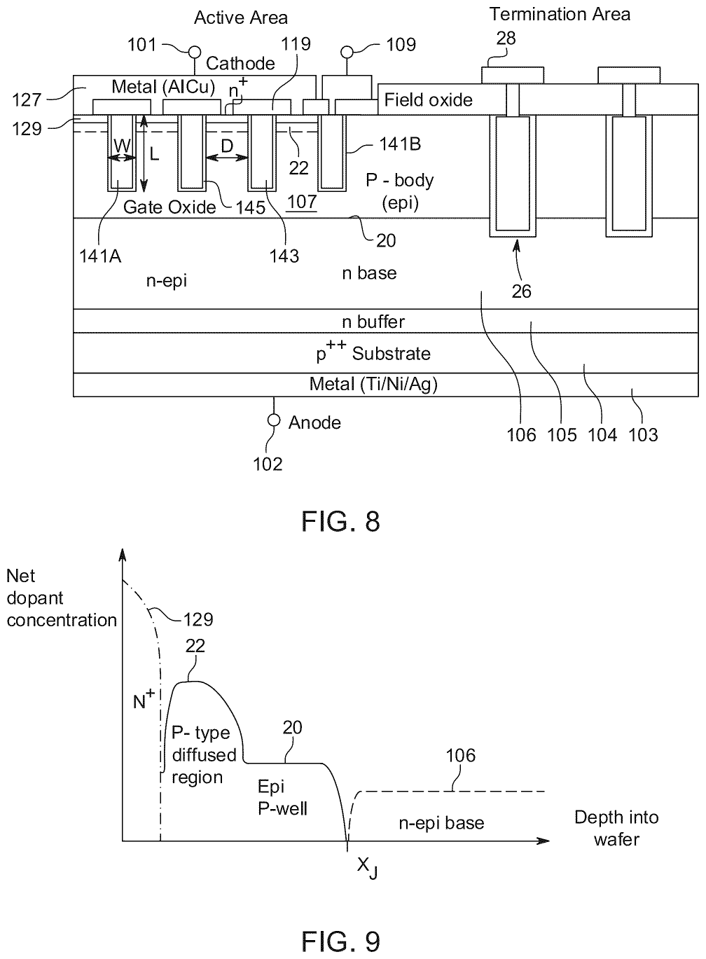

In FIG. 8, n-dopants are implanted in the surface and diffused for a short time to form the n+ source regions 129.

Then, an array of trenches is formed in the active area that terminate in the p-body 20. The trenches are oxidized for form a thin gate oxide 145, then filled with doped polysilicon to form the gates 143.

The various dielectric regions are formed and metal electrodes are formed as discussed with respect to FIG. 1.

To assure electron extraction from the inversion layer along the sides of the gates, the doping concentration in the epitaxial portion of the p-body 20 must satisfy the relation with the distance D (FIG. 8) between the gate trenches in accordance with the following equations:

D<4λ_{D},
where λ_{D} is the Debye length in the lightly doped p-body 20. The Debye length is the distance in a semiconductor layer over which the charge in the inversion layer of a MOS-gated structure is reduced by 1/e, determined by the following equation:

$${λ}_{D} = \sqrt{\frac{{ε}_{0} {k}_{B} {T}_{e}}{{n}_{e} {q}_{e}^{2}}}$$

where ε₀ is the dielectric constant
k_{B} is the Boltzmann constant
Tₑ is the absolute temperature in Kelvin
qₑ is the elementary charge, and
nₑ is the net dopant concentration of p-dopants in the p-body.

As an important consequence of the above equations, we can observe that when the net p-dopant concentration in the p-body 20 is constant (as in the case with an epitaxial p-body). the position of the bottom of the gate trench is not important if it is inside the p-body. This fact leads to a much more controllable gate trench process.

FIG. 8 also shows the termination area on the right side for spreading the voltage potential for increasing the breakdown voltage. In the termination area, there is no enhanced p-layer 22 since the area was masked during the implantation process. In the termination area, deep insulated trenches 26 are formed followed by the trenches 26 being filled with doped polysilicon. The conductive trench areas may be floating or connected to a fixed voltage via metal contacts 28. The trenches 26 form rings that surround the active area. The termination area is inactive since there are no source regions formed in the termination area.

The IGTO device of FIG. 8 has more controllable characteristics compared to the device of FIG. 1, is faster to fabricate, and has more predictable and repeatable characteristics from lot to lot.

FIG. 9 shows a dopant profile of the device of FIG. 8 along the gate trenches. Note how the transitions between regions are more highly defined compared to the profile of FIG. 3.

The shorter time of fabrication of the p-body 20 results in less diffusion of all doped layers that were previously formed, including layers 105 and 106 and the p-type substrate 104. Therefore, the net dopant concentrations are retained, and performance characteristics of all the layers are retained.

Additionally, the dopant concentration of the p-body 20 can be varied continuously during the epitaxial growth process. For example, the p-dopant concentration below the gate trenches can be fairly high to increase the breakdown voltage, while the upper p-dopant concentration can be lower for a larger inversion layer.

By proper selection of the dopant concentration and sizes of the p-body 20 and p-layer 22, the gate trench depths and spacings can be optimized. For example, using the inventive process, the effective p-dopant concentration in the p-layer 22 and p-body 20 can be increased to increase the hole current, allowing a smaller trench spacing and higher current density for the device. This change can be made without reducing the breakdown voltage.

Further, tolerances in the various layers' thicknesses can be reduced since there is less diffusion, resulting in more repeatable performance from lot to lot and higher yields.

Further, the p-body 20 doping concentration and the characteristics of the n-drift layer 106 affect the breakdown voltage in the termination area. So these characteristics can be optimized for breakdown voltage, while the p-layer 22 in the active area can be optimized for turn-on voltage.

When reverse engineering completed devices using a scanning electron microscope, whether a p-body layer is formed by diffusion or epitaxially can be easily determined by techniques used to determine doping concentrations. The epitaxial layer will be much more uniform than a layer that has been formed using implantation and diffusion. Therefore, there are always physical differences between the two types of layers.

The gate trenches in the active area may be formed in strips, in squares, in hexagons, or other shapes to form a 2-dimentional array of cells connected in parallel to create a device having a wide range of current capacities.

The concepts described above can be used to improve the performance of any insulated trench gate device, such as MOSFETs, IGTO devices, IGBTs, thyristors, etc. For a MOSFET, the structure may form an npn device, and the gate trenches extend through a middle p-layer to create an inversion layer that forms a vertical conductive path between the two n-layers.

A lateral device may be formed by providing a highly doped buried layer and a deep sinker to provide both electrodes on top.

The conductivity type of the various layers can be reversed to form a pnpn device.

Various features disclosed may be combined to achieve a desired result.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A method of forming a semiconductor, insulated trench gate switching device comprising:
forming a first semiconductor layer of a first conductivity type over a substrate to form a drift layer;
epitaxially growing a second semiconductor layer of a second conductivity type on the first semiconductor layer to form a first body layer, the second semiconductor layer having a first dopant concentration;
forming a third semiconductor layer of the second conductivity type over the second semiconductor layer to form an enhanced body layer, the third semiconductor layer having a second dopant concentration higher than the first dopant concentration;
forming a fourth semiconductor layer of the first conductivity type over the third semiconductor layer to form source regions;
forming an array of first trenches extending at least into the second semiconductor layer, the trenches having sidewalls;
forming a dielectric layer on the sidewalls;
depositing a first conductive material in the trenches abutting the dielectric layer to form vertical gates;
forming a first electrode contacting the source regions; and
forming a second electrode contacting the substrate,
wherein a top portion of the gates abuts the enhanced body layer, and a bottom portion of the gates abuts the first body layer, such that a threshold voltage applied to the gates inverts the first body layer and the enhanced body layer to form a vertical conductive path for current flow.

2. The method of claim 1 wherein the first trenches and source regions are formed in an active area of the device that conducts current, the method also comprising:
forming second trenches in a termination area of the device between the active area and outer edges of the device, the second trenches being filled with the first conductive material and extending into the first semiconductor layer, wherein there is no enhanced body layer or source region in the termination area.

3. The method of claim 1 wherein forming the enhanced body layer comprises implanting dopants of the second conductivity type into a surface of the first body layer and diffusing the dopants.

4. The method of claim 1 wherein forming the enhanced body layer comprises varying a dopant concentration while epitaxially growing the second semiconductor layer.

5. The method of claim 1 wherein forming the trenches comprises terminating the trenches within the first body layer.

6. The method of claim 1 wherein the substrate is of the second conductivity type.

7. The method of claim 1 wherein the method forms a npnp layered device that is switched on and off by applying voltage to the vertical gates.

8. A semiconductor, insulated trench gate switching device comprising:
a first semiconductor layer of a first conductivity type over a substrate, the first semiconductor layer being a drift layer;
an epitaxially grown second semiconductor layer of a second conductivity type on the first semiconductor layer, the second semiconductor layer being a first body layer, the second semiconductor layer having a first dopant concentration;
a third semiconductor layer of the second conductivity type over the second semiconductor layer, the third semiconductor layer being an enhanced body layer, the third semiconductor layer having a second dopant concentration higher than the first dopant concentration;
a fourth semiconductor layer of the first conductivity type over the third semiconductor layer, the fourth semiconductor layer being source regions;
an array of first trenches in at least the second semiconductor layer, the trenches having sidewalls;
a dielectric layer on the sidewalls;
a first conductive material in the trenches abutting the dielectric layer forming vertical gates;
a first electrode contacting the source regions; and
a second electrode contacting the substrate,
wherein a top portion of the gates abuts the enhanced body layer, and a bottom portion of the gates abuts the first body layer, such that a threshold voltage applied to the gates inverts the first body layer and the enhanced body layer to form a vertical conductive path for current flow.

9. The device of claim 8 wherein the first trenches and source regions are formed in an active area of the device that conducts current, the device also comprising:
second trenches in a termination area of the device between the active area and outer edges of the device, the second trenches being filled with the first conductive material and extending into the first semiconductor layer, wherein the there is no enhanced body layer or source region in the termination area.

10. The device of claim 8 wherein the enhance body layer is formed by implanting dopants of the second conductivity type into a surface of the first body layer and diffusing the dopants.

11. The device of claim 8 wherein the enhance body layer is formed by varying a dopant concentration while epitaxially growing the second semiconductor layer.

12. The device of claim 8 wherein the trenches terminate within the first body layer.

13. The device of claim 8 wherein the substrate is of the second conductivity type.

14. The device of claim 8 wherein the device is a npnp layered device that is switched on and off by applying voltage to the vertical gates.
